(19) United States
(12) Patent Application Publication
(10) Pub. No.: US 2026/0035274 A1
(43) Pub. Date: Feb. 5, 2026

(54) APPARATUS FOR PURIFYING SEMICONDUCTOR MANUFACTURING CHEMICAL LIQUID

(71) Applicant: SAMSUNG ELECTRONICS CO., LTD., Suwon-si (KR)

(72) Inventors: Jinhyeok JANG, Suwon-si (KR); Jihyun KIM, Seoul (KR); Yunho KIM, Suwon-si (KR); Younghun KIM, Suwon-si (KR); Junyoung OH, Suwon-si (KR); Donggyu LEE, Seoul (KR); Seungyun LEE, Seoul (KR); Hyori LEE, Suwon-si (KR); Samjong CHOI, Suwon-si (KR)

(73) Assignees: SAMSUNG ELECTRONICS CO., LTD., Suwon-si (KR); Seoul National University R&DB FOUNDATION, Seoul (KR)

(21) Appl. No.: 19/279,599

(22) Filed: Jul. 24, 2025

(30) Foreign Application Priority Data
Aug. 5, 2024 (KR) 10-2024-0104141
Nov. 5, 2024 (KR) 10-2024-0155684

(51) Int. Cl. C02F 1/463; C02F 1/461; C02F 103/34; H01L 21/67

(52) U.S. Cl. CPC C02F 1/463; C02F 1/46109; H01L 21/67017; C02F 2103/346; C02F 2201/4611

(57) ABSTRACT

An apparatus for purifying a semiconductor manufacturing chemical liquid is provided. The apparatus includes a substrate, a metal pad including a first electrode and a second electrode spaced apart from each other, an insulating layer defining an opening overlapping a first connection portion of the first electrode and an opening overlapping a second connection portion of the second electrode, and an alternating current waveform generator connected to the first electrode and the second electrode, wherein the first electrode includes a first body electrode and a plurality of first branch electrodes, the second electrode includes a second body electrode and a plurality of second branch electrodes, and the plurality of first branch electrodes and the plurality of second branch electrodes are alternately arranged in a second direction.

### CROSS-REFERENCE TO RELATED APPLICATIONS

This application is based on and claims priority under 35 U.S.C. § 119 to Korean Patent Application Nos. 10-2024-0104141, filed on Aug. 5, 2024, and 10-2024-0155684, filed on Nov. 5, 2024, in the Korean Intellectual Property Office, the disclosures of which are herein incorporated by reference in their entireties.

### BACKGROUND

One or more example embodiments of the disclosure relate to an apparatus for purifying a semiconductor manufacturing chemical liquid, and more particularly, to a semiconductor manufacturing chemical liquid purification apparatus for purifying impurities in a semiconductor manufacturing chemical liquid.

Along with the refinement of a semiconductor process, impurities, such as very small-sized particles and metal ions, have become a cause of a defect in a semiconductor device. A filter has been widely used to remove such impurities from various kinds of chemical liquids used in the semiconductor process. However, because the improvement of a filtering function in the related art does not follow the refinement speed of the semiconductor process, the development of a new technique capable of removing very small-sized impurities from a chemical liquid has been required.

### SUMMARY

One or more example embodiments of the disclosure provide a semiconductor manufacturing chemical liquid purification apparatus with improved purification efficiency.

In addition, the problems to be solved by the technical idea of the disclosure are not limited to the problem mentioned above, and other problems could be clearly understood by those of ordinary skill in the art from the description below.

According to an aspect of the disclosure, there is provided an apparatus for purifying a semiconductor manufacturing chemical liquid, the apparatus including a tank configured to store the semiconductor manufacturing chemical liquid including impurities, a pipe through which the semiconductor manufacturing chemical liquid is supplied to the tank or supplied from the tank to an outside of the tank, and an agglomeration structure inside at least one of the tank and the pipe, wherein the agglomeration structure includes a substrate, a metal pad on the substrate and including a first electrode and a second electrode spaced apart from each other, and an insulating layer on the metal pad and defining an opening through which at least a portion of an upper surface of the first electrode is exposed and an opening through which at least a portion of an upper surface of the second electrode is exposed, the first electrode includes a plurality of first branch electrodes extending in a first direction and a first body electrode connecting the plurality of first branch electrodes to each other, the second electrode includes a plurality of second branch electrodes extending in the first direction and a second body electrode connecting the plurality of second branch electrodes to each other, and the plurality of first branch electrodes and the plurality of second branch electrodes are alternately arranged in a second direction intersecting the first direction.

According to another aspect of the disclosure, there is provided an apparatus for purifying a semiconductor manufacturing chemical liquid, the apparatus including a tank configured to store the semiconductor manufacturing chemical liquid including impurities, a pipe through which the semiconductor manufacturing chemical liquid is supplied to the tank or supplied from the tank to an outside of the tank, and an agglomeration structure inside at least one of the tank and the pipe, wherein the agglomeration structure includes a substrate, a metal pad on the substrate and including a first electrode and a second electrode spaced apart from each other, and an insulating layer on the metal pad and defining an opening through which at least a portion of an upper surface of the first electrode is exposed and an opening through which at least a portion of an upper surface of the second electrode is exposed, the first electrode includes a plurality of first branch electrodes extending in a first direction and a first body electrode connecting the plurality of first branch electrodes to each other, the second electrode includes a plurality of second branch electrodes extending in the first direction and a second body electrode connecting the plurality of second branch electrodes to each other, and a distance between the first body electrode and the second body electrode in the first direction is less than a sum of a length of one of the plurality of first branch electrodes in the first direction and a length of one of the plurality of second branch electrodes in the first direction.

According to another aspect of the disclosure, there is provided an apparatus for purifying a semiconductor manufacturing chemical liquid, the apparatus including a substrate, a metal pad on the substrate and including a first electrode and a second electrode spaced apart from each other, an insulating layer on the metal pad and defining an opening overlapping a first connection portion of the first electrode and an opening overlapping a second connection portion of the second electrode, and an alternating current waveform generator connected to the first connection portion of the first electrode and the second connection portion of the second electrode, wherein the first electrode includes a first body electrode and a plurality of first branch electrodes extending in a first direction from the first body electrode, the second electrode includes a second body electrode and a plurality of second branch electrodes extending in the first direction from the second body electrode, and the plurality of first branch electrodes and the plurality of second branch electrodes are alternately arranged in a second direction intersecting the first direction.

### BRIEF DESCRIPTION OF DRAWINGS

Example embodiments of the disclosure will be more clearly understood from the following detailed description taken in conjunction with the accompanying drawings, in which:

FIG. 1 schematically illustrates a semiconductor manufacturing chemical liquid transport system according to one or more embodiments of the disclosure;

FIG. 2 schematically illustrates a semiconductor manufacturing chemical liquid purification apparatus according to one or more embodiments of the disclosure;

FIG. 3 schematically illustrates an agglomeration structure according to one or more embodiments of the disclosure;

FIG. 4 is an enlarged view of portion A of FIG. 3;

FIG. 5A is a cross-sectional view taken along line I-I′ of FIG. 3;

FIG. 5B is a cross-sectional view taken along line II-II′ of FIG. 3;

FIG. 6 schematically illustrates an agglomeration structure according to one or more embodiments of the disclosure;

FIG. 7 schematically illustrates an agglomeration structure according to one or more embodiments of the disclosure; and

FIGS. 8A to 8D are plan views sequentially illustrating a process of forming an agglomeration structure, according to one or more embodiments of the disclosure.

### DETAILED DESCRIPTION

Hereinafter, example embodiments are described in detail with reference to the accompanying drawings. Like reference numerals in the drawings denote like elements, and thus their repetitive description will be omitted.

In the embodiments below, the terms, such as “first” and “second”, are used to classify one element from another element without limiting the elements. Expressions such as “at least one of”, when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

In the embodiments below, an expression in the singular includes an expression in the plural unless they are clearly different from each other in context.

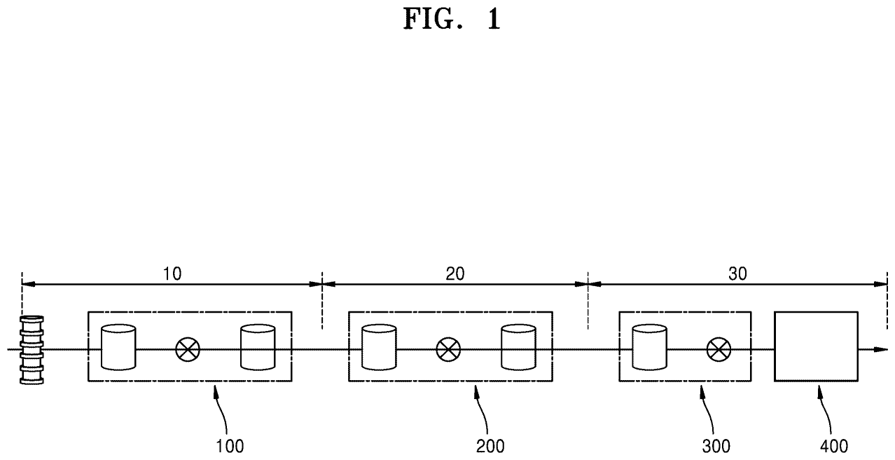

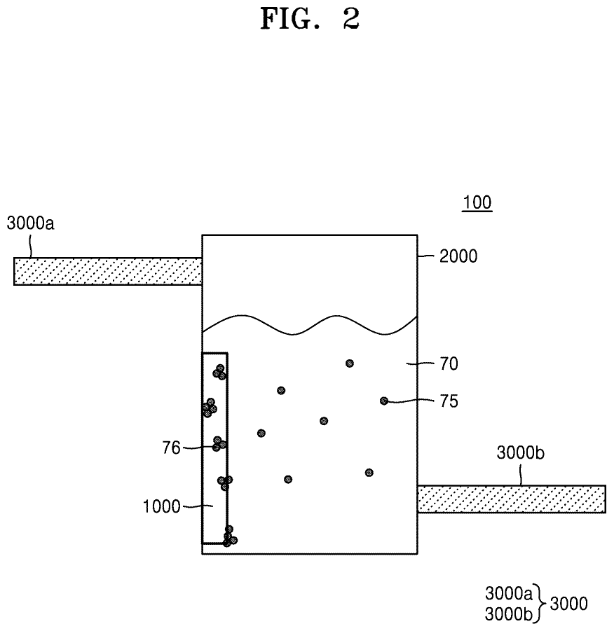

FIG. 1 schematically illustrates a semiconductor manufacturing chemical liquid transport system 1 according to one or more embodiments of the disclosure. FIG. 2 schematically illustrates a semiconductor manufacturing chemical liquid purification apparatus 100 according to one or more embodiments of the disclosure.

Referring to FIGS. 1 and 2, the semiconductor manufacturing chemical liquid transport system 1 may include a manufacturing section 10, a supply section 20, and a processing section 30. The manufacturing section 10 may be configured to manufacture a semiconductor manufacturing chemical liquid 70. The semiconductor manufacturing chemical liquid 70 may include a chemical liquid to be used in a semiconductor process. For example, the semiconductor manufacturing chemical liquid 70 may be a chemical liquid used in a cleaning process, an exposure process, an etching process, a development process, a deposition process, and the like and may include ultra-pure water (UPW), a liquid or gaseous organic compound, a non-ionic fluid, or the like. Alternatively, the semiconductor manufacturing chemical liquid 70 may be a fluid including at least any one of hydrogen peroxide, sulfuric acid, phosphoric acid, hydrochloric acid, ammonia water, isopropyl alcohol (IPA), thinner, tetramethyl ammonium hydroxide (TMAH), developer, and hydrofluoric acid. In some embodiments, the semiconductor manufacturing chemical liquid 70 may include a liquid photoresist. However, the semiconductor manufacturing chemical liquid 70 is not limited thereto, and the semiconductor manufacturing chemical liquid 70 may be any chemical liquid used in a semiconductor manufacturing process and including impurities 75. In addition, the impurities 75 may be present in a state of being dissolved in the semiconductor manufacturing chemical liquid 70 or present in a particular shape. According to embodiments, diameters of the impurities 75 included in the semiconductor manufacturing chemical liquid 70 may be in a range of about 0.5 nm to about 100 nm. However, the diameters of the impurities 75 are not limited to the range.

The supply section 20 may be configured to provide the semiconductor manufacturing chemical liquid 70 manufactured in the manufacturing section 10 to the processing section 30. For example, the supply section 20 may be a place in which the semiconductor manufacturing chemical liquid 70 manufactured in the manufacturing section 10 is temporarily stored before being provided to the processing section 30. In addition, in the supply section 20, the semiconductor manufacturing chemical liquid 70 manufactured in the manufacturing section 10 may be additionally processed. The additional processing may indicate chemical and/or physical processing newly applied to the semiconductor manufacturing chemical liquid 70.

The processing section 30 may be configured to process a wafer by using the semiconductor manufacturing chemical liquid 70 supplied from the supply section 20. According to embodiments, in the processing section 30, a cleaning process, an exposure process, an etching process, a development process, a deposition process, and the like on the wafer may be performed. Various kinds of processes on the wafer may be performed by semiconductor equipment 400. The semiconductor equipment 400 may be configured to perform a process in a semiconductor or display manufacturing line.

According to embodiments, the manufacturing section 10, the supply section 20, and the processing section 30 may include semiconductor manufacturing chemical liquid purification apparatuses 100, 200, and 300, respectively. Because the semiconductor manufacturing chemical liquid purification apparatuses 100, 200, and 300 respectively provided to the manufacturing section 10, the supply section 20, and the processing section 30 are substantially the same as or similar to each other, hereinafter, the semiconductor manufacturing chemical liquid purification apparatus 100 provided to the manufacturing section 10 is mainly described.

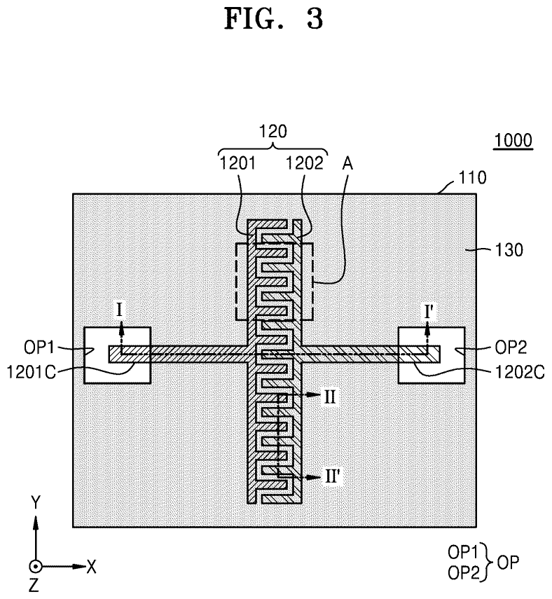

The semiconductor manufacturing chemical liquid purification apparatus 100 may include an agglomeration structure 1000, a tank 2000, and a pipe 3000. In some embodiments, the agglomeration structure 1000 may be inside at least one of the tank 2000 and the pipe 3000. A detailed description of the agglomeration structure 1000 is made below with reference to FIG. 3.

The pipe 3000 may be configured to supply the semiconductor manufacturing chemical liquid 70 to the tank 2000 or supply the semiconductor manufacturing chemical liquid 70 from the tank 2000 to an outside of the tank 2000. The pipe 3000 may include a first pipe 3000a and a second pipe 3000b. The first pipe 3000a may be configured to supply the semiconductor manufacturing chemical liquid 70 to the tank 2000. The first pipe 3000a may provide a path through which the semiconductor manufacturing chemical liquid 70 manufactured by semiconductor manufacturing chemical liquid manufacturing equipment is supplied to the tank 2000. The first pipe 3000a may be physically connected to the tank 2000. In some embodiments, the first pipe 3000a may be connected to an upper portion of the tank 2000.

The tank 2000 may be configured to store the semiconductor manufacturing chemical liquid 70. The tank 2000 may be a tank configured to store the semiconductor manufacturing chemical liquid 70 to be purified and may be configured to store a fluid or a gas. For example, when a high-pressure gas is stored, the tank 2000 may be a ball tank. For example, when a volatile fluid is stored, the tank 2000 may be a tank having a floating roof. According to embodiments, the tank 2000 may be configured to store both the agglomeration structure 1000 and the semiconductor manufacturing chemical liquid 70.

The tank 2000 may include an inlet port and an outlet port. The inlet port may be an inlet through which the semiconductor manufacturing chemical liquid 70 is introduced, and the outlet port may be an outlet through which the semiconductor manufacturing chemical liquid 70 is discharged. According to embodiments, the inlet port may be connected to the first pipe 3000a, and the outlet port may be connected to the second pipe 3000b. According to embodiments, one of the inlet port and the outlet port may be located at the upper portion of the tank 2000, and the other one may be located at a lower portion of the tank 2000. According to embodiments, the outlet port may be configured to switch between an off state in which the semiconductor manufacturing chemical liquid 70 stored in the tank 2000 is not introduced to the second pipe 3000b and an on state in which the semiconductor manufacturing chemical liquid 70 is introduced to the second pipe 3000b. According to embodiments, the outlet port may maintain the off state when the semiconductor manufacturing chemical liquid 70 in the tank 2000 is processed by the agglomeration structure 1000. In addition, the outlet port may be switched to the on state when the semiconductor manufacturing chemical liquid 70 is completely processed by the agglomeration structure 1000.

According to embodiments, a first valve and a first pump may be located on the first pipe 3000a. The first valve may be configured to control a flow of the semiconductor manufacturing chemical liquid 70 flowing through the first pipe 3000a. For example, the first valve may turn on or off introduction of the semiconductor manufacturing chemical liquid 70 flowing through the first pipe 3000a to the tank 2000. In addition, the first valve may adjust a flow rate of the semiconductor manufacturing chemical liquid 70 flowing through the first pipe 3000a. According to embodiments, the first valve may be switched to the off state when a certain amount or more of the semiconductor manufacturing chemical liquid 70 is stored in the tank 2000. Accordingly, no more semiconductor manufacturing chemical liquid 70 may be supplied to the tank 2000. The first pump may be configured to control the flow of the semiconductor manufacturing chemical liquid 70 flowing through the first pipe 3000a. For example, the first pump may control the flow of the semiconductor manufacturing chemical liquid 70 by adjusting a pressure inside the first pipe 3000a. The first pump may turn on or off introduction of the semiconductor manufacturing chemical liquid 70 flowing through the first pipe 3000a to the tank 2000. In addition, the first pump may adjust the flow rate of the semiconductor manufacturing chemical liquid 70 flowing through the first pipe 3000a.

The second pipe 3000b may be configured to provide a path through which the semiconductor manufacturing chemical liquid 70 stored in the tank 2000 moves to the outside of the tank 2000. The second pipe 3000b may be configured to supply the semiconductor manufacturing chemical liquid 70 stored in the tank 2000 to the outside of the tank 2000. The semiconductor manufacturing chemical liquid 70 processed by the agglomeration structure 1000 in the tank 2000 may be supplied to the second pipe 3000b.

According to embodiments, in the second pipe 3000b, at least any one of a second valve and a second pump may be formed. The second valve may be configured to adjust a flow of the semiconductor manufacturing chemical liquid 70 flowing through the second pipe 3000b. For example, the second valve may turn on or off the flow of the semiconductor manufacturing chemical liquid 70 flowing through the second pipe 3000b. In addition, the second valve may adjust a flow rate of the semiconductor manufacturing chemical liquid 70 flowing through the second pipe 3000b. According to embodiments, the second valve may maintain the off state until the semiconductor manufacturing chemical liquid 70 is completely processed by the agglomeration structure 1000 in the tank 2000. However, the second valve may maintain the on state when the semiconductor manufacturing chemical liquid 70 is completely processed by the agglomeration structure 1000 in the tank 2000. The second pump may be configured to control the flow of the semiconductor manufacturing chemical liquid 70 flowing through the second pipe 3000b. For example, the second pump may control the flow of the semiconductor manufacturing chemical liquid 70 by adjusting the pressure inside the second pipe 3000b. The second pump may turn on or off discharge of the semiconductor manufacturing chemical liquid 70 flowing through the second pipe 3000b from the tank 2000. In addition, the second pump may adjust the flow rate of the semiconductor manufacturing chemical liquid 70 flowing through the second pipe 3000b.

Although FIG. 2 shows that the agglomeration structure 1000 is located inside the tank 2000, the embodiments are not limited thereto. In one or more embodiments, the agglomeration structure 1000 may be located inside at least one of the tank 2000 and the pipe 3000. That is, the agglomeration structure 1000 may be located inside the first pipe 3000a and/or the second pipe 3000b.

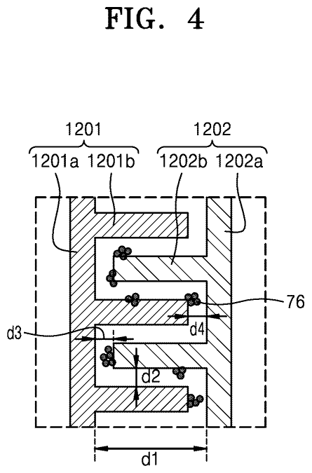

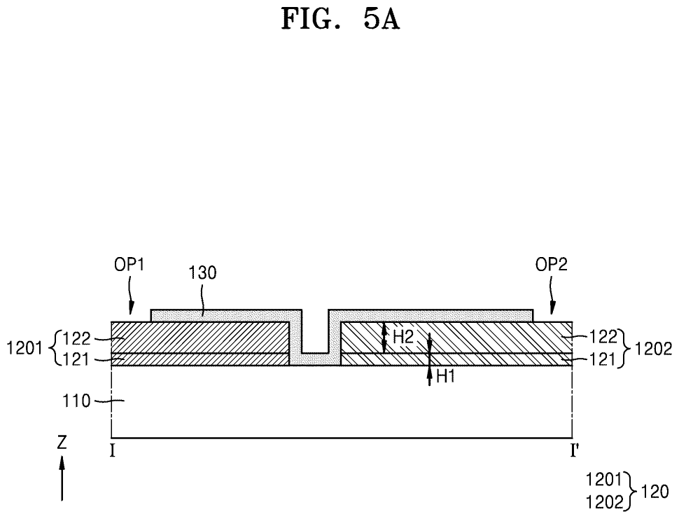

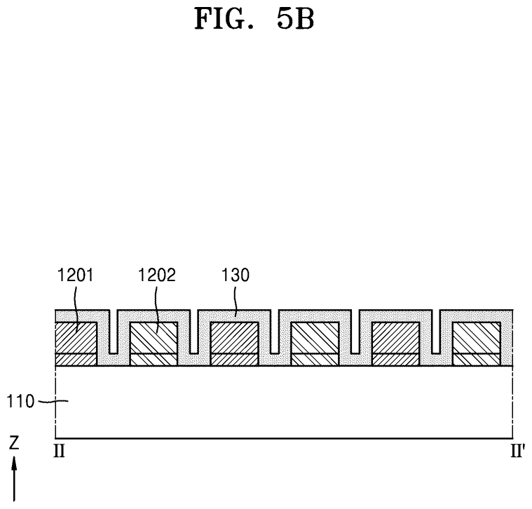

FIG. 3 schematically illustrates the agglomeration structure 1000 according to one or more embodiments of the disclosure. FIG. 4 is an enlarged view of portion A of FIG. 3, FIG. 5A is a cross-sectional view taken along line I-I′ of FIG. 3, and FIG. 5B is a cross-sectional view taken along line II-II′ of FIG. 3.

The agglomeration structure 1000 may be configured to agglomerate the impurities 75 (see FIG. 2) included in the semiconductor manufacturing chemical liquid 70 (see FIG. 2). The agglomeration structure 1000 may form an impurity lump 76 by agglomerating the impurities 75 (see FIG. 2) included in the semiconductor manufacturing chemical liquid 70 (see FIG. 2).

Referring to FIG. 3, the agglomeration structure 1000 may include a substrate 110, a metal pad 120, and an insulating layer 130. In an embodiment, the substrate 110 may be a sapphire substrate, but the embodiments are not limited thereto. For example, the substrate 110 may be a silicon substrate. The metal pad 120 may be disposed on the substrate 110. The metal pad 120 may include a first electrode 1201 and a second electrode 1202 spaced apart from each other. One of the first electrode 1201 and the second electrode 1202 may act as a cathode, and the other one thereof may act as an anode. In some embodiments, polarities of the first electrode 1201 and the second electrode 1202 may depend on a progress of a process.

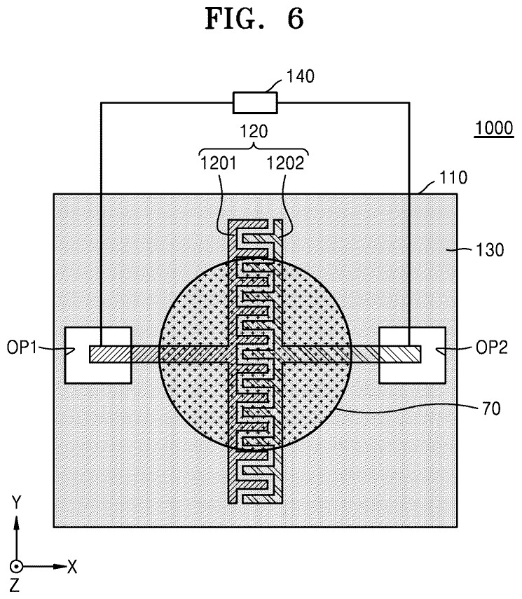

As described below, an alternating current waveform generator 140 (see FIG. 6) may be connected to the first electrode 1201 and the second electrode 1202. When the alternating current waveform generator 140 (see FIG. 6) supplies an alternating current to each of the first electrode 1201 and the second electrode 1202, a non-uniform electric field may be generated between the first electrode 1201 and the second electrode 1202.

The non-uniform electric field may apply a dielectrophoretic force to permanent and/or induced dipoles of the impurities 75 (see FIG. 2) included in the semiconductor manufacturing chemical liquid 70 (see FIG. 2) stored in the tank 2000 (see FIG. 2). Accordingly, as shown in FIG. 2 or FIG. 4, the impurities 75 (see FIG. 2) may agglomerate with each other to form impurity lumps 76. The impurity lumps 76 may be formed when a plurality of impurities 75 (see FIG. 2) agglomerate with each other.

Particularly, when an alternating current voltage is applied to each of the first electrode 1201 and the second electrode 1202 by the alternating current waveform generator 140 (see FIG. 6), an electric field may be formed between the first electrode 1201 and the second electrode 1202. In this case, because the alternating current voltage is applied to the first electrode 1201 and the second electrode 1202, a line of electric force may be induced from the second electrode 1202 to the first electrode 1201 or from the first electrode 1201 to the second electrode 1202. Accordingly, an electric field of a non-uniform gradient may be generated between the first electrode 1201 and the second electrode 1202.

When the line of electric force is induced from the second electrode 1202 to the first electrode 1201, the line of electric force may be induced in a form of diffusing toward the first electrode 1201 from the second electrode 1202. That is, a gradient of an electric field near the second electrode 1202 may be greater than a gradient of an electric field near the first electrode 1201. Therefore, a relatively stronger electric field may be formed on the second electrode 1202, and a relatively weaker electric field may be formed on the first electrode 1201.

The impurities 75 (see FIG. 2) may agglomerate due to the gradient of the non-uniform electric field. For example, when the impurities 75 (see FIG. 2) have no polarity, the impurities 75 (see FIG. 2) may have an electric dipole shape by an electric dipole induction phenomenon due to the non-uniform electric field. A magnitude and a direction of a polarity induced to the impurity 75 (see FIG. 2) may depend on a frequency of an electric field, and dielectric properties, such as a conductivity and a permittivity, of the semiconductor manufacturing chemical liquid 70 (see FIG. 2) and the impurity 75 (see FIG. 2). According to embodiments, diameters of the impurity lumps 76 may be within a range of about 100 nm to about 10 μm. In some embodiments, the diameters of the impurity lumps 76 may be within a range of about 1 μm to about 5 μm.

According to embodiments, when an electric field is formed in the semiconductor manufacturing chemical liquid 70 by the agglomeration structure 1000, the impurities 75 may agglomerate with each other to form the impurity lumps 76, be attached to surfaces of the first electrode 1201 and the second electrode 1202, or still drift in the semiconductor manufacturing chemical liquid 70. In an embodiment, the agglomeration structure 1000 may be detached from the tank 2000 and/or the pipe 3000 to remove collected impurity lumps 76, or a filter may be used to remove impurity lumps 76 drifting in the semiconductor manufacturing chemical liquid 70. In some embodiments, the filter may include, for example, a point of use (POU) filter, a disposable filter, or a bulk cartridge filter. In some embodiments, the filter may be attached to an inside of the second pipe 300b or connected to the second pipe 3000b.

When the impurities 75 present inside the semiconductor manufacturing chemical liquid 70 are removed using the filter, to filter out small-sized impurities 75, it may be required that pores of a membrane formed in the filter be small. In particular, when the impurities 75 have diameters of a nanometer unit, it may be required that sizes of the pores of the membrane in the filter be of a nanometer unit, and accordingly, the semiconductor manufacturing chemical liquid 70 may be stagnant without easily passing through the filter.

To address this problem, the semiconductor manufacturing chemical liquid purification apparatus 100 according to one or more embodiments of the disclosure may agglomerate the impurities 75 in the semiconductor manufacturing chemical liquid 70 through the agglomeration structure 1000 to form the impurity lumps 76, and thus, the pores of the filter may be formed to have a relatively large size. That is, the flow of the semiconductor manufacturing chemical liquid 70 may be maintained without being stagnant, and impurities may be removed through agglomeration.

In some embodiments, the impurity 75 included in the semiconductor manufacturing chemical liquid 70 may be a material having a low permittivity. For example, a relative permittivity of the impurity 75 may be 9 or less. For example, the impurity 75 may be silicon dioxide (SiO₂) of which the relative permittivity is 3.9. When an impurity has a low permittivity, an effect of agglomerating impurities by dielectrophoresis in general parallel electrodes may be insignificant. The metal pad 120 included in the agglomeration structure 1000 according to one or more embodiments may include the first electrode 1201 and the second electrode 1202 formed in a micropattern, thereby maximizing an effect of agglomerating impurities by an electric field, as described above.

Referring to FIGS. 3 and 4, the first electrode 1201 may include a first body electrode 1201a and a plurality of first branch electrodes 1201b. The first body electrode 1201a may connect the plurality of first branch electrodes 1201b to each other. Each of the plurality of first branch electrodes 1201b may extend in a first direction (e.g., an X direction). In an embodiment, the first body electrode 1201a may include a first portion extending in a second direction (e.g., a Y direction) to connect the plurality of first branch electrodes 1201b to each other and a second portion in which a first connection portion 1201C for connection to an alternating current waveform generator (e.g., 140 in FIG. 6) is defined.

The second electrode 1202 may include a second body electrode 1202a and a plurality of second branch electrodes 1202b. The second body electrode 1202a may connect the plurality of second branch electrodes 1202b to each other. Each of the plurality of second branch electrodes 1202b may extend in the first direction (e.g., the X direction). In an embodiment, the second body electrode 1202a may include a first portion extending in the second direction (e.g., the Y direction) to connect the plurality of second branch electrodes 1202b to each other and a second portion in which a second connection portion 1202C for connection to an alternating current waveform generator (e.g., 140 in FIG. 6) is defined.

Referring to FIGS. 3 and 4, the plurality of first branch electrodes 1201b and the plurality of second branch electrodes 1202b may be alternately arranged in the second direction (e.g., the Y direction). A distance d1 between the first body electrode 1201a and the second body electrode 1202a in the first direction (e.g., the X direction) may be less than a sum of a length of one of the plurality of first branch electrodes 1201b in the first direction (e.g., the X direction) and a length of one of the plurality of second branch electrodes 1202b in the first direction (e.g., the X direction).

The distance d1 between the first body electrode 1201a and the second body electrode 1202a in the first direction (e.g., the X direction) may be within a range of about 1 μm to about 1000 μm. In an embodiment, because the agglomeration structure 1000 agglomerates impurities to form relatively large-sized impurity lumps, the distance d1 between the first body electrode 1201a and the second body electrode 1202a may be set to 1 μm or greater, thereby improving impurity agglomeration efficiency. In addition, the distance d1 between the first body electrode 1201a and the second body electrode 1202a may be set to 1000 μm or less, thereby maximizing the electric field effect described above.

In some embodiments, each of a distance d2 between any one of the plurality of first branch electrodes 1201b and the most adjacent one of the plurality of second branch electrodes 1202b, a distance d3 between the first body electrode 1201a and one of the plurality of second branch electrodes 1202b, and a distance d4 between one of the plurality of first branch electrodes 1201b and the second body electrode 1202a may be set to a range of about 1 μm to about 100 μm.

Referring to FIGS. 3, 5A, and 5B, the metal pad 120 may be disposed on the substrate 110 and include a first metal pad 121 and a second metal pad 122 sequentially stacked on the substrate 110. In some embodiments, a thickness H2 of the second metal pad 122 may be greater than a thickness H1 of the first metal pad 121. The first metal pad 121 may be an auxiliary layer for easily depositing the second metal pad 122 on the substrate 110. The first metal pad 121 may be an adhesive layer for adhesion between the second metal pad 122 and the substrate 110. In an embodiment, the first metal pad 121 may include titanium (Ti), and the second metal pad 122 may include gold (Au), but the embodiment is not limited thereto, and each of the first metal pad 121 and the second metal pad 122 may include at least one of various types of conductive materials.

The insulating layer 130 may cover at least a portion of the metal pad 120 on the substrate 110. The insulating layer 130 may define an opening OP through which at least a portion of an upper surface of the metal pad 120 is exposed. The opening OP may include a first opening OP1 through which at least a portion of an upper surface of the first electrode 1201 of the metal pad 120 is exposed and a second opening OP2 through which at least a portion of an upper surface of the second electrode 1202 of the metal pad 120 is exposed. Accordingly, the first opening OP1 may define the first connection portion 1201C of the first electrode 1201, and the second opening OP2 may define the second connection portion 1202C of the second electrode 1202.

FIG. 6 schematically illustrates the agglomeration structure 1000 according to one or more embodiments of the disclosure. The alternating current waveform generator 140 may also be applied to the agglomeration structure 1000 shown in FIGS. 2 and 3.

Referring to FIG. 6, the alternating current waveform generator 140 may be connected to each of the first electrode 1201 and the second electrode 1202. Particularly, the alternating current waveform generator 140 may be connected to the first connection portion 1201C (see FIG. 3) of the first electrode 1201, which is exposed through the first opening OP1 defined by the insulating layer 130. The alternating current waveform generator 140 may be connected to the second connection portion 1202C (see FIG. 3) of the second electrode 1202, which is exposed through the second opening OP2 defined by the insulating layer 130.

The alternating current waveform generator 140 may supply an alternating current to the first electrode 1201 and the second electrode 1202. However, in some embodiments, the alternating current waveform generator 140 may supply a direct current to the first electrode 1201 and the second electrode 1202 depending on circumstances. According to embodiments, the alternating current waveform generator 140 may apply a voltage in a range of about −50 V to about +50 V to each of the first electrode 1201 and the second electrode 1202. According to embodiments, an output frequency of the alternating current waveform generator 140 may be within a range of about 1 kHz to about 10 MHz.

As described above, when the alternating current waveform generator 140 supplies an alternating current to the first electrode 1201 and the second electrode 1202, a non-uniform electric field may be generated between the first electrode 1201 and the second electrode 1202 to agglomerate the impurities 75 (see FIG. 2) included in the semiconductor manufacturing chemical liquid 70 (see FIG. 2). Accordingly, the impurities 75 (see FIG. 2) included in the semiconductor manufacturing chemical liquid 70 (see FIG. 2) may be removed.

The agglomeration structure 1000 according to one or more embodiments may be arranged inside the tank 2000 configured to store the semiconductor manufacturing chemical liquid 70, as shown in FIG. 2, but the embodiments are not limited thereto. In some embodiments, as shown in FIG. 6, the semiconductor manufacturing chemical liquid 70 may be dropped in the agglomeration structure 1000 to agglomerate impurities in the semiconductor manufacturing chemical liquid 70.

Alternatively, the agglomeration structure 1000 may be formed even in the semiconductor equipment 400 (see FIG. 1). For example, the agglomeration structure 1000 formed in the semiconductor equipment 400 (see FIG. 1) may agglomerate the impurities 75 (see FIG. 2) in the semiconductor manufacturing chemical liquid 70 to form the impurity lumps 76 (see FIG. 2) and then remove the impurity lumps 76 (see FIG. 2) before the semiconductor manufacturing chemical liquid 70 is discharged onto a wafer. Accordingly, impurities 75 inside the semiconductor manufacturing chemical liquid 70 discharged onto the wafer may be minimized.

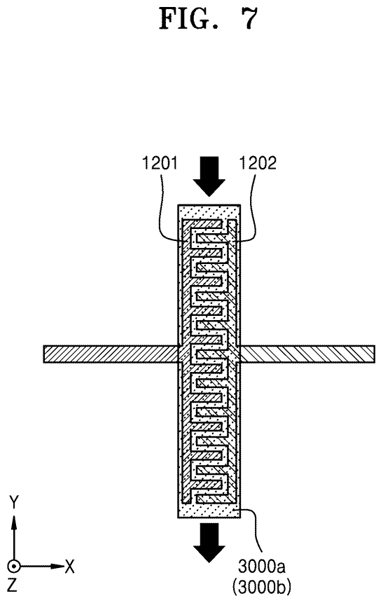

FIG. 7 schematically illustrates an agglomeration structure according to one or more embodiments of the disclosure.

Referring to FIG. 7, the first electrode 1201 and the second electrode 1202 according to one or more embodiments may be located inside the first pipe 3000a or the second pipe 3000b. In an embodiment, the plurality of first branch electrodes 1201b (see FIG. 4) of the first electrode 1201 and the plurality of second branch electrodes 1202b (see FIG. 4) of the second electrode 1202 may be arranged inside the first pipe 3000a or the second pipe 3000b. In an embodiment, at least a portion of the first body electrode 1201a (see FIG. 4) of the first electrode 1201 and at least a portion of the second body electrode 1202a (see FIG. 4) of the second electrode 1202 may be located inside the first pipe 3000a. In an embodiment, at least a portion of the first body electrode 1201a (see FIG. 4) of the first electrode 1201 and at least a portion of the second body electrode 1202a (see FIG. 4) of the second electrode 1202 may be located outside the first pipe 3000a.

As shown in FIG. 7, when the first electrode 1201 and the second electrode 1202 are arranged inside the first pipe 3000a or the second pipe 3000b, the semiconductor manufacturing chemical liquid 70 (see FIG. 2) flowing through the first pipe 3000a or the second pipe 3000b may be continuously provided to the first electrode 1201 and the second electrode 1202.

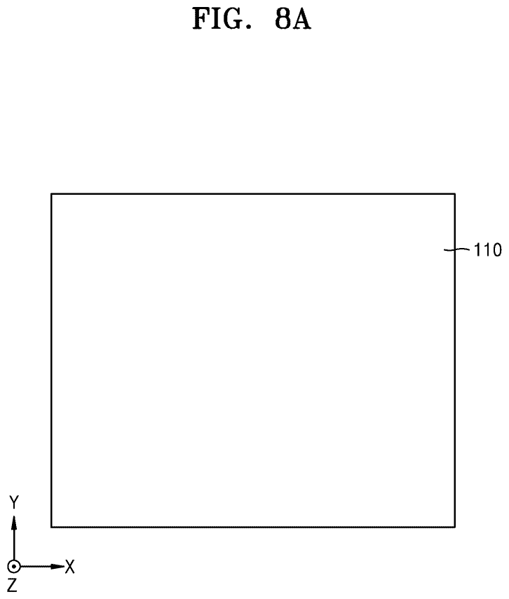

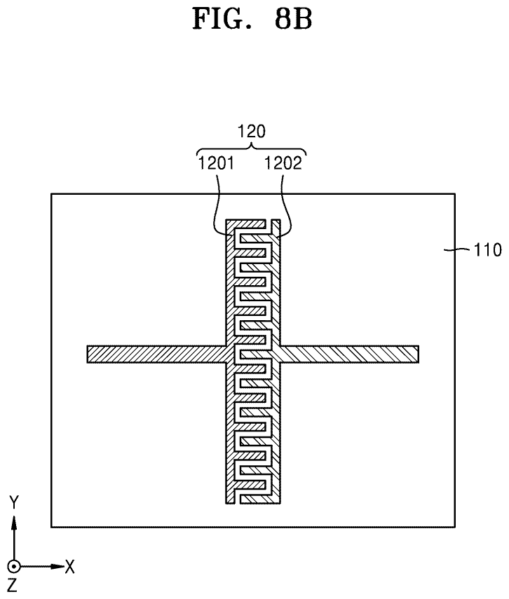

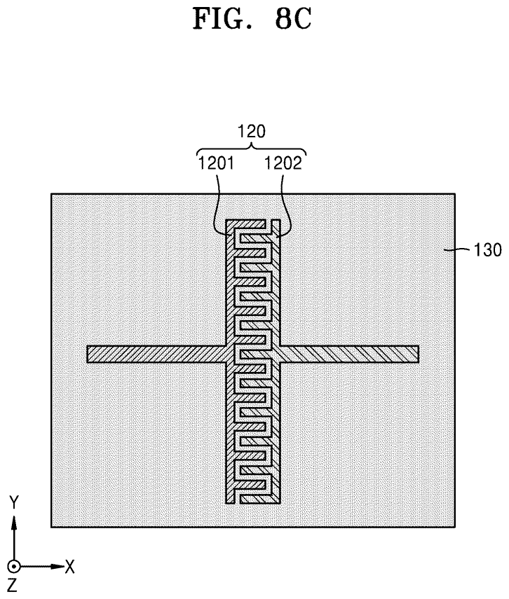

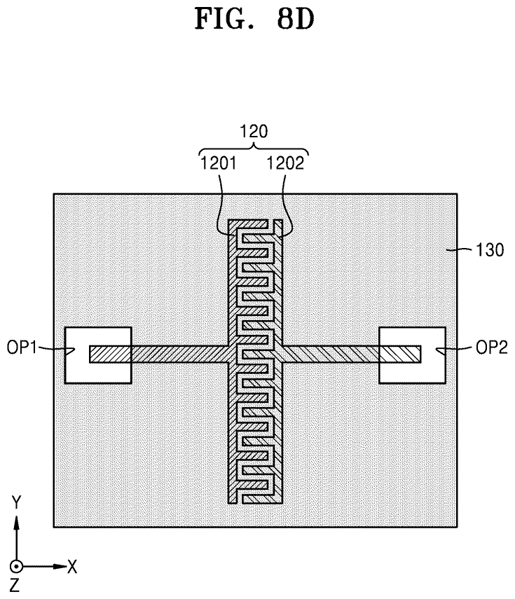

FIGS. 8A to 8D are plan views (or top views) sequentially illustrating a process of forming an agglomeration structure, according to one or more embodiments of the disclosure.

Referring to FIGS. 8A and 8B, first, the substrate 110 may be prepared, and then, the metal pad 120 may be formed on the substrate 110. In an embodiment, the substrate 110 may be a sapphire substrate or a silicon substrate. A photoresist layer may be formed on the substrate 110, and then, exposure and development may be performed on the photoresist layer. Thereafter, a metal may be deposited on the photoresist layer, and the metal pad 120 of a micropattern may be formed from the metal through lift-off. In an embodiment, the first electrode 1201 and the second electrode 1202 may be simultaneously formed and include the same material.

Referring to FIGS. 5A and 8B, the metal pad 120 may be formed through two operations. In some embodiments, the first metal pad 121 may be first formed on the substrate 110 to facilitate deposition of the second metal pad 122 on the substrate 110 thereafter. That is, by forming the second metal pad 122 after forming the first metal pad 121 of the metal pad 120, the first electrode 1201 and the second electrode 1202 of a micropattern may be stably formed.

Referring to FIG. 8C, the insulating layer 130 may be deposited on the substrate 110. In an embodiment, the insulating layer 130 may be formed by atomic layer deposition (ALD). In this stage, the insulating layer 130 may fully cover the metal pad 120 of the micropattern.

Referring to FIG. 8D, a portion of the insulating layer 130 may be etched to form the first opening OP1 and the second opening OP2. The first opening OP1 and the second opening OP2 may be formed by removing portions of the insulating layer 130 such that the first opening OP1 and the second opening OP2 overlap at least a portion of the first electrode 1201 and at least a portion of the second electrode 1202, respectively. The first opening OP1 may expose at least a portion of the upper surface of the first electrode 1201, and the second opening OP2 may expose at least a portion of the upper surface of the second electrode 1202. The first opening OP1 and the second opening OP2 may expose portions (e.g., the first connection portion 1201C (see FIG. 3) and the second connection portion 1202C (see FIG. 3)) of the upper surfaces of the first electrode 1201 and the second electrode 1202 such that the first electrode 1201 and the second electrode 1202 are connected to an electronic device, such as the alternating current waveform generator 140 (see FIG. 6). In an embodiment, the alternating current waveform generator 140 (see FIG. 6) may supply an alternating current to the first electrode 1201 and the second electrode 1202 to generate a non-uniform electric field.

The semiconductor manufacturing chemical liquid purification apparatus 100 according to one or more embodiments may include the substrate 110, the metal pad 120, and the insulating layer 130. The substrate 110, the metal pad 120, and the insulating layer 130 may constitute the agglomeration structure 1000. The metal pad 120 may include the first electrode 1201 and the second electrode 1202 of the micropattern described above to maximize an electric force generated by the first electrode 1201 and the second electrode 1202. Accordingly, the impurities 75 included in the semiconductor manufacturing chemical liquid 70 may agglomerate with each other. When the agglomerated impurity lumps 76 are attached to the agglomeration structure 1000, the impurity lumps 76 may be directly and effectively removed from the agglomeration structure 1000. When the agglomerated impurity lumps 76 drift in the semiconductor manufacturing chemical liquid 70, a filter may be applied to the inside or the like of a pipe (e.g., the second pipe 3000b) through which the semiconductor manufacturing chemical liquid 70 passes, thereby effectively removing the impurity lumps 76. Because the filter requires only pores enough to remove the impurity lumps 76 having a relatively large size, interruption to a flow of the semiconductor manufacturing chemical liquid 70 due to the filter may be minimized.

At least one of the components, elements, modules or units (collectively “components” in this paragraph) represented by a block in the drawings may be embodied as various numbers of hardware, software and/or firmware structures that execute respective functions described above, according to an example embodiment. According to example embodiments, at least one of these components may use a direct circuit structure, such as a memory, a processor, a logic circuit, a look-up table, etc. that may execute the respective functions through controls of one or more microprocessors or other control apparatuses. Also, at least one of these components may be specifically embodied by a module, a program, or a part of code, which contains one or more executable instructions for performing specified logic functions, and executed by one or more microprocessors or other control apparatuses. Further, at least one of these components may include or may be implemented by a processor such as a central processing unit (CPU) that performs the respective functions, a microprocessor, or the like. Two or more of these components may be combined into one single component which performs all operations or functions of the combined two or more components. Also, at least part of functions of at least one of these components may be performed by another of these components. Functional aspects of the above example embodiments may be implemented in algorithms that execute on one or more processors. Furthermore, the components represented by a block or processing steps may employ any number of related art techniques for electronics configuration, signal processing and/or control, data processing and the like.

While the disclosure has been particularly shown and described with reference to example embodiments thereof, it will be understood that various changes in form and details may be made therein without departing from the spirit and scope of the following claims and their equivalents.

What is claimed is:

1. An apparatus for purifying a semiconductor manufacturing chemical liquid, the apparatus comprising:
a tank configured to store the semiconductor manufacturing chemical liquid including impurities;
a pipe through which the semiconductor manufacturing chemical liquid is supplied to the tank or supplied from the tank to an outside of the tank; and
an agglomeration structure inside at least one of the tank and the pipe,
wherein the agglomeration structure comprises a substrate, a metal pad on the substrate and including a first electrode and a second electrode spaced apart from each other, and an insulating layer on the metal pad and defining an opening through which at least a portion of an upper surface of the first electrode is exposed and an opening through which at least a portion of an upper surface of the second electrode is exposed,
wherein the first electrode comprises a plurality of first branch electrodes extending in a first direction and a first body electrode connecting the plurality of first branch electrodes to each other,
wherein the second electrode comprises a plurality of second branch electrodes extending in the first direction and a second body electrode connecting the plurality of second branch electrodes to each other, and
wherein the plurality of first branch electrodes and the plurality of second branch electrodes are alternately arranged in a second direction intersecting the first direction.

2. The apparatus of claim 1, wherein a distance between the first body electrode and the second body electrode in the first direction is within a range of about 1 μm to about 1000 μm.

3. The apparatus of claim 1, further comprising an alternating current waveform generator connected to the first electrode and the second electrode.

4. The apparatus of claim 3, wherein the alternating current waveform generator is connected to a first connection portion of the first electrode and a second connection portion of the second electrode, the first connection portion and the second connection portion being exposed by the openings of the insulating layer.

5. The apparatus of claim 3, wherein the alternating current waveform generator is configured to apply a voltage in a range of about −50 V to about +50 V to each of the first electrode and the second electrode.

6. The apparatus of claim 3, wherein an output frequency of the alternating current waveform generator is within a range of about 1 kHz to about 10 MHz.

7. The apparatus of claim 1, wherein each of the first electrode and the second electrode comprises a first metal pad and a second metal pad sequentially stacked on the substrate.

8. The apparatus of claim 7, wherein a thickness of the second metal pad is greater than a thickness of the first metal pad.

9. The apparatus of claim 1, wherein the agglomeration structure is inside the tank,
wherein diameters of the impurities in the semiconductor manufacturing chemical liquid supplied to the tank through the pipe are within a range of about 0.5 nm to about 100 nm, and
wherein the agglomeration structure is configured to agglomerate the impurities into impurity lumps, diameters of which are within a range of about 100 nm to about 10 μm.

10. The apparatus of claim 1, wherein the semiconductor manufacturing chemical liquid includes at least any one of hydrogen peroxide, sulfuric acid, phosphoric acid, hydrochloric acid, ammonia water, isopropyl alcohol, thinner, tetramethyl ammonium hydroxide, developer, and hydrofluoric acid.

11. An apparatus for purifying a semiconductor manufacturing chemical liquid, the apparatus comprising:
a tank configured to store the semiconductor manufacturing chemical liquid including impurities;
a pipe through which the semiconductor manufacturing chemical liquid is supplied to the tank or supplied from the tank to an outside of the tank; and
an agglomeration structure inside at least one of the tank and the pipe,
wherein the agglomeration structure comprises a substrate, a metal pad on the substrate and including a first electrode and a second electrode spaced apart from each other, and an insulating layer on the metal pad and defining an opening through which at least a portion of an upper surface of the first electrode is exposed and an opening through which at least a portion of an upper surface of the second electrode is exposed,
wherein the first electrode comprises a plurality of first branch electrodes extending in a first direction and a first body electrode connecting the plurality of first branch electrodes to each other,
wherein the second electrode comprises a plurality of second branch electrodes extending in the first direction and a second body electrode connecting the plurality of second branch electrodes to each other, and
wherein a distance between the first body electrode and the second body electrode in the first direction is less than a sum of a length of one of the plurality of first branch electrodes in the first direction and a length of one of the plurality of second branch electrodes in the first direction.

12. The apparatus of claim 11, wherein a distance between one of the plurality of first branch electrodes and the second body electrode in the first direction is within a range of about 1 μm to about 100 μm.

13. The apparatus of claim 11, wherein the first electrode and the second electrode include a same material.

14. The apparatus of claim 11, further comprising an alternating current waveform generator connected to the first electrode and the second electrode.

15. The apparatus of claim 14, wherein the alternating current waveform generator is connected to a first connection portion of the first electrode and a second connection portion of the second electrode, the first connection portion and the second connection portion being exposed by the openings of the insulating layer.

16. The apparatus of claim 11, wherein the agglomeration structure is inside the tank,
wherein diameters of the impurities in the semiconductor manufacturing chemical liquid supplied to the tank through the pipe are within a range of about 0.5 nm to about 100 nm, and
wherein the agglomeration structure is configured to agglomerate the impurities into impurity lumps, diameters of which are within a range of about 100 nm to about 10 μm.

17. The apparatus of claim 11, wherein a relative permittivity of the impurities is 9 or less.

18. The apparatus of claim 11, wherein each of the first electrode and the second electrode comprises a first metal pad and a second metal pad sequentially stacked on the substrate.

19. An apparatus for purifying a semiconductor manufacturing chemical liquid, the apparatus comprising:
a substrate;
a metal pad on the substrate and comprising a first electrode and a second electrode spaced apart from each other;
an insulating layer on the metal pad and defining an opening overlapping a first connection portion of the first electrode and an opening overlapping with a second connection portion of the second electrode; and
an alternating current waveform generator connected to the first connection portion of the first electrode and the second connection portion of the second electrode,
wherein the first electrode comprises a first body electrode and a plurality of first branch electrodes extending in a first direction from the first body electrode,
wherein the second electrode comprises a second body electrode and a plurality of second branch electrodes extending in the first direction from the second body electrode, and
wherein the plurality of first branch electrodes and the plurality of second branch electrodes are alternately arranged in a second direction intersecting the first direction.

20. The apparatus of claim 19, further comprising:
a tank configured to store a semiconductor manufacturing chemical liquid including impurities; and
a pipe through which the semiconductor manufacturing chemical liquid is supplied to the tank or supplied from the tank to an outside of the tank,
wherein the substrate, the metal pad, and the insulating layer are inside at least one of the tank and the pipe, and
wherein a distance between the first body electrode and the second body electrode in the first direction is within a range of about 1 μm to about 1000 μm.
